(19) United States
(12) Patent Application Publication
(10) Pub. No.: US 2025/0392140 A1
(43) Pub. Date: Dec. 25, 2025

(54) CHARGING SYSTEM

(71) Applicant: TOYOTA JIDOSHA KABUSHIKI KAISHA, Toyota-shi (JP)

(72) Inventors: Hiroshi YOSHIDA, Anjo-shi (JP); Yuki Sugo, Seto-shi (JP); Yoshiki Tsuchida, Nagoya-shi (JP); Kazuki Kubo, Toyota-shi (JP)

(73) Assignee: TOYOTA JIDOSHA KABUSHIKI KAISHA, Toyota-shi (JP)

(21) Appl. No.: 19/223,559

(22) Filed: May 30, 2025

(30) Foreign Application Priority Data
Jun. 21, 2024 (JP) 2024-100316

(51) Int. Cl. H02J 7/00

(52) U.S. Cl. CPC H02J 7/0029; H02J 7/0048; H02J 7/005; H02J 7/007182

(57) ABSTRACT

A charging system includes a controller configured to perform charging control of a battery in such a manner that an estimated SOC value of the battery does not exceed an upper limit SOC. The controller is configured to set the upper limit SOC to a first SOC value, for the battery not having been swollen, and set the upper limit SOC to a second SOC value lower than the first SOC value, for the battery having been swollen. In response to a determination that the battery has been swollen and an SOC estimation error is large, the controller is configured to cause an SOC of the battery to be higher than the second SOC value, and determine a correction parameter for correcting the SOC estimation error.

### CROSS REFERENCE TO RELATED APPLICATIONS

This nonprovisional application is based on Japanese Patent Application No. 2024-100316 filed on Jun. 21, 2024 with the Japan Patent Office, the entire contents of which are hereby incorporated by reference.

### BACKGROUND

### Field

The present disclosure relates to a charging system that performs charging control of a battery.

### Description of the Background Art

Japanese Patent Laying-Open No. 2019-220260 discloses a system that performs charging control so that the SOC (State Of Charge) of a battery does not exceed the upper limit SOC.

### SUMMARY

For example, the generation of gas inside the battery may cause the battery to swell. The swelling of the battery degrades the performance of the battery. Overcharge of the battery promotes swelling of the battery. Therefore, it is conceivable to lower the upper limit SOC in order to suppress swelling of the battery. However, when the upper limit SOC is lowered, the accuracy of SOC estimation may decrease. When the accuracy of the SOC estimation decreases, even if the charging control of the battery is performed so that the estimated SOC value does not exceed the upper limit SOC, there is a possibility that the actual SOC of the battery exceeds the upper limit SOC due to the estimation error. Therefore, when the accuracy of SOC estimation decreases, it becomes difficult to sufficiently suppress the swelling of the battery by the upper limit SOC.

The present disclosure has been made to solve the above-described problem, and an object of the present disclosure is to facilitate suppression of swelling of a battery by an upper limit SOC.

A charging system according to one aspect of the present disclosure includes a controller configured to perform charging control of a battery in such a manner that an estimated SOC value of the battery does not exceed an upper limit SOC. The controller is configured to set the upper limit SOC to a first SOC value, for the battery not having been swollen, and set the upper limit SOC to a second SOC value lower than the first SOC value, for the battery having been swollen. In response to a determination that the battery has been swollen and an SOC estimation error is large, the controller is configured to cause an SOC of the battery to be higher than the second SOC value, and determine a correction parameter for correcting the SOC estimation error.

The foregoing and other objects, features, aspects and advantages of the present disclosure will become more apparent from the following detailed description of the present disclosure when taken in conjunction with the accompanying drawings.

### BRIEF DESCRIPTION OF THE DRAWINGS

FIG. 1 is a diagram illustrating a configuration of a charging system according to an embodiment of the present disclosure.

FIG. 2 is a diagram showing an internal configuration of the battery pack shown in FIG. 1.

FIG. 3 is a flowchart showing the SOC estimation correction method according to the present embodiment.

FIG. 4 is a flowchart showing details of the correction parameter updating process shown in FIG. 3.

FIG. 5 is a diagram showing a modification of the power storage system shown in FIG. 1.

FIG. 6 is a flowchart showing a modification of the process flow shown in FIG. 2.

### DESCRIPTION OF THE PREFERRED EMBODIMENTS

Embodiments of the present disclosure will be described in detail below with reference to the drawings. The same or corresponding elements in the drawings have the same reference characters allotted and description thereof will not be repeated.

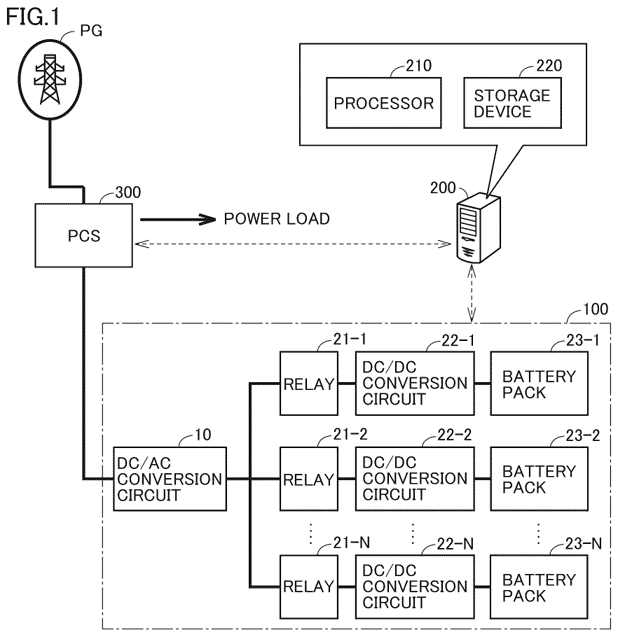

FIG. 1 is a diagram illustrating a configuration of a charging system according to an embodiment of the present disclosure. As shown in FIG. 1, the charging system according to this embodiment includes a power storage system 100, a server 200, and PCS (Power Conditioning System) 300. The charging system may be installed in a building (e.g., a residential, factory, public, or commercial facility).

The server 200 executes charging control for storing power supplied from the power grid PG (external power source) in the power storage system 100. In addition, the server 200 executes discharging control for supplying power discharged from the power storage system 100 to the power load. Examples of power loads include electromechanical equipment (lighting equipment, air conditioning equipment, etc.) used in buildings. The PCS 300 includes a power path switching device and a power conversion circuit, and operates in accordance with an instruction from the server 200.

In this embodiment, the power grid PG supplies AC power. The power grid PG is an electric power network constructed by electric power transmission and distribution facilities. The power grid PG may include a power generation facility and/or a power transformation facility. The server 200 may perform power adjustment (for example, adjustment of supply and demand balance) of the power grid PG using the power storage system 100.

The power storage system 100 includes a DC/AC conversion circuit 10, N relays 21-1 to 21-N (hereinafter referred to as a “relay 21” unless they are distinguished), N DC/DC conversion circuits 22-1 to 22-N (hereinafter referred to as a “DC/DC conversion circuit 22” unless they are distinguished), and N battery packs 23-1 to 23-N (hereinafter referred to as a “battery pack 23” unless they are distinguished). The power storage system 100 is controlled by the server 200. N is, for example, 2 or more and 100 or less, and may be about 30. Here, N is arbitrary.

The battery packs 23-1 to 23-N are connected in parallel to each other. The battery packs 23-1 to 23-N are provided with relays 21-1 to 21-N and DC/DC conversion circuits 22-1 to 22-N, respectively. The relay 21 is provided in an electric path connecting the DC/AC conversion circuit 10 and the DC/DC conversion circuit 22. The relay 21 is, for example, an electromagnetic mechanical relay. Each of the relays 21-1 to 21-N switches between energization and de-energization of the corresponding battery pack 23 in accordance with an instruction from the server 200.

When DC power is input from the battery pack 23 to the DC/DC conversion circuit 22, the DC/DC conversion circuit 22 outputs DC power according to an instruction from the server 200 to the DC/AC conversion circuit 10. The DC/AC conversion circuit 10 outputs AC power according to an instruction from the server 200 to the PCS 300. The PCS 300 performs power conversion on the received AC power, and outputs the AC power after the power conversion to at least one of the power grid PG and the power load.

The PCS 300 is supplied with AC power from the power grid PG. PCS 300 performs power conversion on the received AC power, and outputs the AC power after power conversion to at least one of DC/AC conversion circuit 10 and the power load. The DC/AC conversion circuit 10 converts AC power input from the PCS 300 into DC power. When AC power is input from the power grid PG to the DC/AC conversion circuit 10 via the PCS 300, the DC/AC conversion circuit 10 outputs DC power according to an instruction from the server 200 to each of the DC/DC conversion circuits 22-1 to 22-N. The DC/DC conversion circuit 22 converts the DC power input from the DC/AC conversion circuit 10, and outputs the DC power according to the instruction from the server 200 to the corresponding battery pack 23.

The server 200 includes a processor 210 and a storage device 220. The battery packs 23-1 to 23-N are registered in the server 200. The storage device 220 stores information (for example, specifications and control information) relating to each battery pack in such a manner as to be distinguished by identification information of the battery pack.

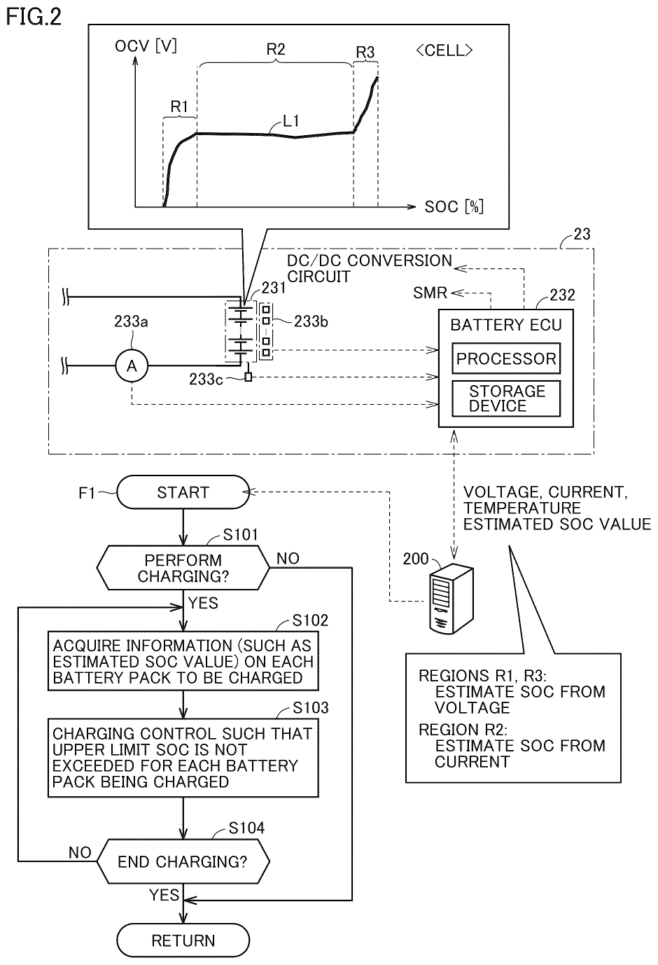

FIG. 2 is a diagram illustrating a configuration of the battery pack 23. The battery pack 23 corresponds to a stationary power storage device. As shown in FIG. 2, the battery pack 23 includes a power storage device 231, a battery ECU (Electronic Control Unit) 232, a current sensor 233a, a voltage sensor 233b, and a temperature sensor 233c. The detection results of the respective sensors are input to the battery ECU 232.

In this embodiment, the power storage device 231 is a battery assembly. The battery assembly includes a plurality of secondary batteries electrically connected to each other. Hereinafter, each secondary battery included in the battery assembly is referred to as a “cell”. The power storage device 231 may include a switch circuit that selectively disconnects some of the cells from the battery assembly. The current sensor 233a detects a current flowing through the power storage device 231. The voltage sensor 233b detects the voltage of each cell included in the power storage device 231. The temperature sensor 233c detects the temperature of the power storage device 231. In this embodiment, a plurality of cells are connected in series in power storage device 231, and the current value detected by current sensor 233a is used as a current value common to the plurality of cells included in power storage device 231. Without being limited as such, in a form in which the power storage device 231 includes a plurality of cells connected in parallel, the battery ECU 232 may calculate the current value of each cell using the current value detected by the current sensor.

The battery ECU 232 includes a processor and a storage device, and records the detection result of each sensor in the storage device in association with the detection time. Although details will be described later, the battery ECU 232 estimates the SOC (State Of Charge) of each cell from the detection result of each sensor, and records the estimated SOC value in the storage device in association with the time. The SOC indicates a ratio of a current amount of stored power to an amount of stored power in a fully charged state. The battery ECU 232 outputs data recorded in the storage device to the server 200 in response to a request from the server 200. The battery ECU 232 controls each of the corresponding relay 21 and DC/DC conversion circuit 22 in accordance with a command from the server 200.

In this embodiment, each cell included in the power storage device 231 (battery assembly) is a lithium-ion secondary battery. Specifically, a lithium-ion secondary battery (hereinafter referred to as “LFP battery”) employing lithium iron phosphate as a positive electrode active material is employed as a cell. The relationship between the OCV and the SOC of such a cell is represented by a line L1 in FIG. 2, for example.

A line L1 indicates an OCV-SOC curve (horizontal axis: SOC, vertical axis: OCV) of a cell (LFP battery) included in the power storage device 231. OCV means Open Circuit Voltage. The higher the SOC, the greater the amount of power stored. Hereinafter, in the OCV-SOC curve, the amount of change in the amount of stored power (SOC) is expressed as “dQ”, the amount of change in the voltage (OCV) is expressed as “dV”, and the ratio of the amount of change in the voltage to the amount of change in the amount of stored power is expressed as “dV/dQ”.

The OCV-SOC curve indicated by the line L1 has regions R1 to R3. The region R1 is located near the SOC (0%) in the empty state. The region R3 is located near the SOC (100%) in the fully charged state. The region R2 is located between the region R1 and the region R3. The OCV-SOC curve is divided into a flat region and a steep region. The flat region is a region in which dV/dQ is smaller than the reference value. The steep region is a region in which dV/dQ is larger than the reference value. Each of the regions R1 and R3 corresponds to a steep region. The region R2 corresponds to a flat region (plateau region). The reference value may be 0.0001 V/mAh or more and 0.0200 V/mAh or less, or may be 0.005 V/mAh or more and 0.010 V/mAh or less. However, the reference value is not limited to these numerical ranges, and can be arbitrarily set in accordance with the OCV-SOC curve of the battery.

By charging a battery in an empty state (for example, a state in which the SOC is “0%”), the region to which the SOC of the battery belongs shifts from the region R1 to the region R2. Further, when the charging is continued, the region to which the SOC of the battery belongs shifts from the region R2 to the region R3. In any of the regions R1 to R3, there is a one-to-one correspondence between the OCV and the SOC.

In this embodiment, the OCV-SOC curve (initial OCV-SOC curve) of each cell included in the power storage device 231 is stored in advance in the storage device of the battery ECU 232. The OCV-SOC curve held by the battery ECU 232 may be an OCV-SOC curve common to a plurality of cells. The charge characteristics of the LFP battery tend to be an OCV-SOC curve including a steep region in the vicinity of the SOC in the fully charged state and a flat region on the low SOC side of the steep region, for example, as indicated by a line L1. The battery ECU 232 determines whether the SOC of the cell belongs to the flat region or the steep region based on the OCV-SOC curve of the cell.

When the SOC of the cell belongs to the steep region, the battery ECU 232 estimates the SOC of the cell from the OCV of the cell with reference to the OCV-SOC curve of the cell. In such a method, the SOC of the battery can be estimated with higher accuracy when the SOC of the battery is in a steep region (a region where dV/dQ is large) than when the SOC of the battery is in a flat region (a region where dV/dQ is small). This is because, in the steep region, even a slight change in the amount of stored power greatly changes the battery voltage. Hereinafter, a method of estimating the SOC of a cell when the SOC of the cell belongs to a steep region is also referred to as a “first estimation method”. The OCV of the cell is detected by, for example, the voltage sensor 233b.

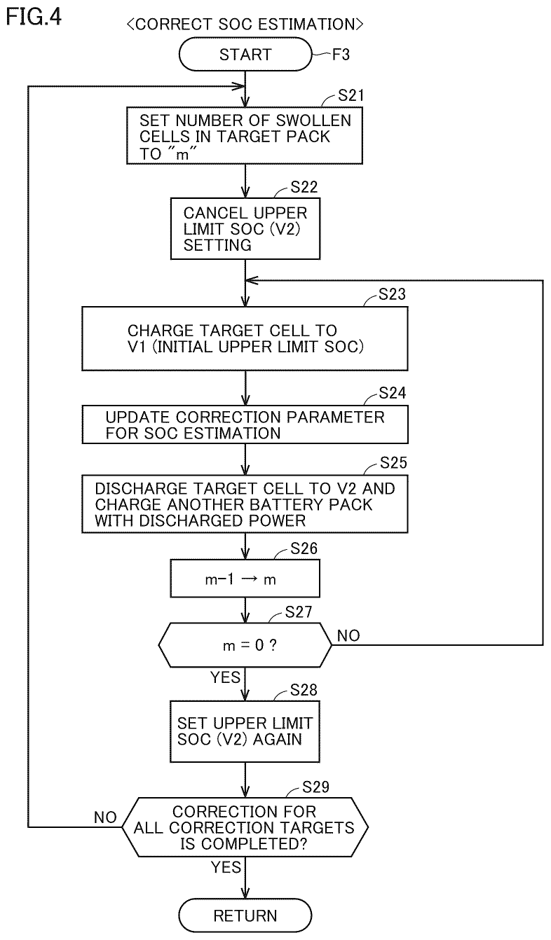

On the other hand, when the SOC of the cell belongs to the flat region, the battery ECU 232 estimates the SOC of the cell using the current of the cell detected by the current sensor 233a and the correction parameter. The battery ECU 232 estimates the SOC of the cell by, for example, a coulomb count method. Hereinafter, a method of estimating the SOC of a cell when the SOC of the cell belongs to a flat region is also referred to as a “second estimation method”. The correction parameter in the second estimation method is stored in the storage device of the battery ECU 232, and is updated by a process described later (see S24 of FIG. 4).

The server 200 sets the upper limit SOC for each of the battery packs 23-1 to 23-N. The set upper limit SOC is stored in the storage device of the battery ECU 232 in association with the identification information of the corresponding battery pack. The storage device of the battery ECU 232 stores, for each battery pack, information for each cell (secondary battery) constituting the power storage device 231 in such a manner that the information is distinguished by cell identification information (cell ID). The storage device of the battery ECU 232 stores, for each cell, for example, a correction parameter (hereinafter also referred to as a “first correction parameter”) for the output value of the current sensor 233a and a correction parameter (hereinafter also referred to as a “second correction parameter”) in the second estimation method described above. The first correction parameter may be a correction value (for example, a correction coefficient) that is added to, subtracted from, multiplied by, or divided by the output value of the current sensor 233a. The second correction parameter may be a correction value (e.g., a correction coefficient) that is added to, subtracted from, multiplied by, or divided by the value of the estimated SOC (estimated SOC value).

Before charging the battery pack (power storage device 231), the server 200 acquires the upper limit SOC set for the battery pack. While the battery pack is being charged, the battery ECU 232 in the battery pack estimates the SOC of each cell included in the battery pack. As described above, the battery ECU 232 switches the SOC estimation method (the first estimation method and the second estimation method) for the cell based on the SOC of the cell. When the SOC of the cell belongs to the steep region, the server 200 may update at least one of the first and second correction parameters based on the estimated SOC value obtained by the first estimation method. In at least one of the first and second estimation methods, the battery ECU 232 may estimate the SOC of the cell by further using the temperature of the cell. The server 200 acquires the estimated SOC value of each cell from the battery ECU 232, and executes the charging control so that the estimated SOC value of each cell does not exceed the upper limit SOC. FIG. 2 is a flowchart showing charging control according to this embodiment. The process flow F1 illustrated in FIG. 2 is repeatedly executed by the server 200. “S” in the flowchart means a step.

As shown in FIG. 2, in S101, server 200 determines whether or not to charge at least one of battery packs 23-1 to 23-N. If the predetermined charging start condition is satisfied, YES is determined in S101, and the process proceeds to S102. As a result, charging is executed in S103. On the other hand, when the charging start condition is not satisfied, NO is determined in S101, and the process flow F1 ends. While the charging start condition is not satisfied, the determination of S101 is repeatedly executed, and charging is not executed.

The charging start condition is satisfied, for example, when charging for SOC adjustment to be described later (see S23 of FIG. 4) is executed. In addition, the charging start condition may be satisfied when the server 200 receives a request for charging for energy management (for example, power adjustment of the power grid PG) by demand response, for example. The server 200, upon receiving such a request, may choose one or more battery packs to charge for energy management.

In S102, the server 200 acquires the upper limit SOC of the corresponding battery pack and the estimated SOC value of each cell from the battery ECU 232 of each battery pack to be charged.

In subsequent S103, the server 200 executes charging control of each battery pack to be charged. Specifically, the server 200 controls the DC/AC conversion circuit 10 so that DC power is supplied from the power grid PG to each battery pack to be charged. Further, for each battery pack to be charged, the server 200 controls the charging power (charging current and charging voltage) through the corresponding DC/DC conversion circuit 22 by connecting the corresponding relay 21. In this charging control, the power storage device 231 is charged so that the estimated SOC value of each cell included in the power storage device 231 does not exceed the upper limit SOC set in the corresponding battery pack 23.

In step S104, the server 200 determines whether a predetermined charging end condition is satisfied. For example, when the SOC of the power storage device 231 (for example, the highest SOC value among the estimated SOC values of the cells) reaches the target value, the charging end condition is satisfied. Regarding the charging started in response to the request, the charging end condition is satisfied when the requested charging is completed. When the estimated SOC value of any of the cells reaches the upper limit SOC, the charging end condition is satisfied. While the charging end condition is not satisfied (NO in S104), the processes of S102 and S103 are repeatedly executed, and the above-described charging control (S103) is continuously executed. On the other hand, when the charging end condition is satisfied (YES in S104), the process flow F1 ends. As a result, the current charging is ended, and the determination of S101 is executed again.

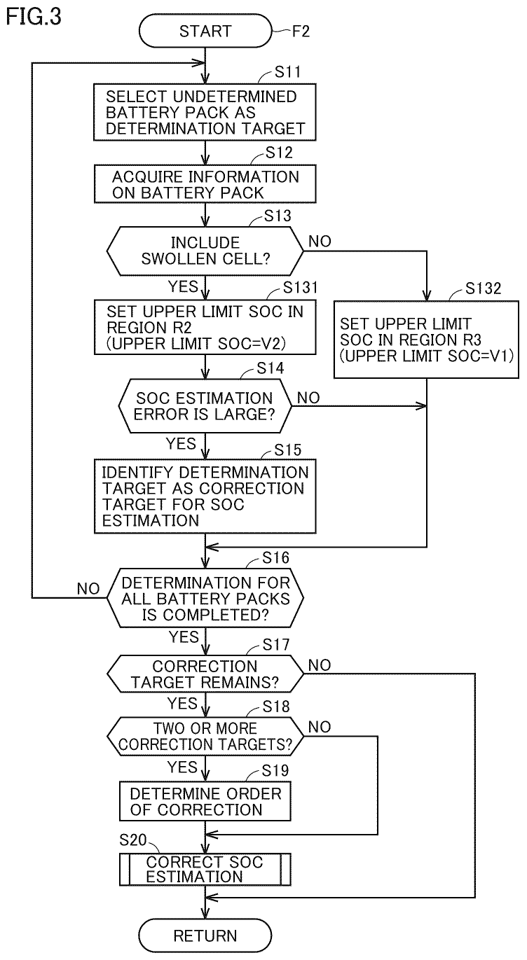

FIG. 3 is a flowchart showing a process for managing SOC estimation accuracy of each battery pack. The process flow F2 illustrated in FIG. 3 is repeatedly executed by the server 200, for example.

As shown in FIG. 3, in S11, server 200 selects an undetermined battery pack from among battery packs 23-1 to 23-N as a determination target. In this embodiment, it is first determined whether or not correction is to be performed for each of the N battery packs in the order of the battery pack 23-1 and the battery packs 23-2, 23-3, . . . , 23-N. However, the determination order can be changed as appropriate.

In subsequent S12, the server 200 acquires predetermined information (hereinafter referred to as “determination information”) regarding the battery pack selected in S11 from the battery ECU 232 of the battery pack (determination target). The determination information includes an OCV-SOC curve, voltage data, and current data. The current data includes a total charging amount and a zero output value, which will be described later.

In subsequent S13, the server 200 determines whether or not the determination target includes the swollen cell using the determination information acquired in S12. Specifically, for each cell included in the determination target, the server 200 determines whether or not the cell is swollen. The server 200 acquires the number of swollen cells for the determination target by determining the presence or absence of swelling for each cell. In this embodiment, the server 200 determines whether or not the cell is swollen based on whether or not the integral value of the charging current of the cell (hereinafter, also referred to as “total charging amount”) is equal to or greater than a predetermined value. The greater the total charging amount of the cell, the more likely the cell swells. However, the method of determining the presence or absence of swelling is not limited to such a method, and may be any method. For example, in a form in which a surface pressure sensor is provided in each cell, the server 200 may determine the presence or absence of swelling based on the surface pressure of the cell.

When it is determined that one or more cells are swollen for the determination target, YES is determined in S13, and the process proceeds to S131. In S131, the server 200 sets the SOC value (hereinafter, referred to as “V2”) in the flat region (region R2 in FIG. 2) as the upper limit SOC of the determination target. V2 may be a fixed value in the flat region or may be variable. The server 200 may lower V2 in the flat region as the total charging amount of the swollen cells increases.

When the process of S131 is executed, in S14, the server 200 determines whether or not the error of the SOC estimation in the determination target is large based on the output value (hereinafter, also referred to as a “zero output value”) when no current flows in the current sensor 233a of the determination target. Specifically, when the SOC of the cell belongs to the flat region, the battery ECU 232 estimates the SOC of the cell using the current of the cell detected by the current sensor 233a. Therefore, in the case where a current value larger than zero or a current value smaller than zero (negative current value) is detected by the current sensor 233a when no current flows through the power storage device 231 in the determination target, there is a high possibility that a detection error also occurs in the SOC estimation of the cell. In this embodiment, server 200 determines whether or not the error in SOC estimation is large based on whether or not the degree of deviation (hereinafter referred to as “current detection error”) between the current detected by current sensor 233a and zero (0 A) when no current flows through power storage device 231 is greater than a predetermined threshold. When the output value of the current sensor 233a is corrected by the correction parameter (first correction parameter), the current value after the correction corresponds to the detected current value. After calculating the current detection error, the server 200 updates the first correction parameter using the current detection error so as to reduce the detection error of the current sensor 233a. The updated first correction parameter is transmitted from the server 200 to the determination target, and is set in the battery ECU 232 of the determination target.

If the current detection error is larger than the threshold, YES is determined in S14, and the process proceeds to S15. In S15, the server 200 identifies the battery pack (determination target) selected in S11 as a correction target related to SOC estimation (hereinafter, also simply referred to as a “correction target”). On the other hand, when the current detection error is equal to or less than the threshold, NO is determined in S14, and the process skips S15 and proceeds to S16. In this case, the server 200 recognizes that the determination target is not a correction target.

When it is determined that none of the cells included in the determination target is swollen (NO in S13), the upper limit SOC is set by the process of S132, and then the process proceeds to S16. In this case, the server 200 recognizes that the determination target is not a correction target. In S132, the server 200 sets an SOC value (hereinafter, referred to as “V1”) in a steep region (region R3 in FIG. 2) on the higher SOC side than the flat region as the upper limit SOC of the determination target. In the battery pack in the initial state, since none of the cells is swollen, V1 is set as the upper limit SOC. V1 corresponds to the initial upper limit SOC. In this embodiment, V1 is a fixed value selected from the SOC range of 90% or more and 100% or less. V1 may be 100%. However, it is not essential that V1 be a fixed value, and may be variable in the steep region (for example, the region R3). The upper limit SOC set in S131 or S132 is transmitted from the server 200 to the determination target, and is set in the battery ECU 232 of the determination target.

In S16, the server 200 determines whether or not the above determination (determination as to whether or not the battery pack is a correction target) has been completed for all of the battery packs 23-1 to 23-N. If the above determination has not been completed for any of the battery packs (NO in S16), the process returns to S11, and the battery pack that has not been determined yet is set as the determination target in S11. When the above determination is executed for all the battery packs, YES is determined in S16, and the process proceeds to S17.

In S17, the server 200 determines whether or not there is a battery pack identified as a correction target in S15 among the battery packs 23-1 to 23-N. When there is no correction target (NO in S17), the process flow F2 ends. In this case, the correction related to the SOC estimation (update of the correction parameter) is not performed. However, the process flow F2 is repeatedly executed.

On the other hand, when there is a correction target (YES in S17), the server 200 determines whether or not the number of correction targets is two or more in S18. When the number of correction targets is two or more (YES in S18), the server 200 determines a correction order for those correction targets in S19. The server 200 may determine the correction order based on the number of swollen cells. However, the method of determining the order of correction is arbitrary. Thereafter, the process proceeds to S20. On the other hand, when the number of correction targets is one (NO in S18), the process skips S19 and proceeds to S20.

In S20, the server 200 updates the correction parameter for correcting the SOC estimation error with respect to the swollen cells included in the correction target (battery pack). FIG. 4 is a flowchart showing details of S20 (correction parameter update processing). In the process flow F3 shown in FIG. 4, the processing of S21 and subsequent steps is executed for the target pack. The target pack is a battery pack identified as a correction target in S15 of FIG. 3. When the number of correction targets is two or more, one correction target (uncorrected correction target) is selected according to the correction order determined in S19 of FIG. 3.

In S21, the server 200 sets the number of swollen cells included in the target pack to a parameter (hereinafter referred to as “m”) indicating the number of uncorrected cells. Subsequently, in S22, the server 200 cancels the setting of the upper limit SOC for the target pack. The current upper limit SOC for the target pack is the latest V2 set in S131 of FIG. 3.

In S23, the server 200 charges the swollen cells until the SOC of the swollen cells included in the target pack reaches the first target value higher than the cancelled upper limit SOC (V2). In this embodiment, the initial upper limit SOC (V1 initially set in S132 of FIG. 3) is set as the first target value. Hereinafter, the swollen cell to be charged is referred to as a “target cell”. When the number of swollen cells in the target pack is two or more, one target cell (uncorrected cell) is selected from these cells. The server 200 may select a target cell in descending order of SOC from among a plurality of swollen cells. However, the method of determining the target cell is arbitrary.

In S23, the server 200 charges the target cell according to the process flow F1 illustrated in FIG. 2. However, since the setting of the upper limit SOC is canceled in S22, the upper limit SOC in the charging control is invalidated. Therefore, in S103 of FIG. 2, the charging of the target pack is not limited by the upper limit SOC. The server 200 can charge the target cell to an initial upper limit SOC (V1) higher than the current upper limit SOC (V2). In a form in which the power storage device 231 is configured to be capable of individually charging and discharging each cell, the server 200 charges only the target cell. However, the target cell may be charged together with other cells.

When the SOC of the target cell reaches the first target value (V1) by the charging, the server 200 updates the correction parameter (second correction parameter) for correcting the SOC estimation error related to the target cell in S24. Specifically, the server 200 acquires the estimated SOC value (first estimated SOC value) of the target cell according to the first estimation method and the estimated SOC value (second estimated SOC value) of the target cell according to the second estimation method from the battery ECU 232 of the target pack, and obtains the correction parameter (second correction parameter) in the second estimation method based on these estimated SOC values. Since the SOC of the target cell is within the steep region, it is considered that the first estimated SOC value (the estimated SOC value based on the OCV-SOC curve) is closer to the true value than the second estimated SOC value (the estimated SOC value based on the current integral value). Therefore, the server 200 updates the second correction parameter so that the estimated value by the second estimation method approaches the first SOC estimated value. The updated second correction parameter is transmitted from the server 200 to the determination target, and is set in the battery ECU 232 of the determination target. This improves the estimation accuracy by the second estimation method.

In subsequent S25, the server 200 discharges the target cell so that the SOC of the target cell in the target pack (first battery pack) becomes the second target value equal to or less than the upper limit SOC (V2) cancelled in S22, and charges the other battery pack (second battery pack) with the discharged power. The first and second battery packs are included in the battery packs 23-1 to 23-N shown in FIG. 1. The server 200 controls the power storage system 100 so that power is exchanged between the battery packs. In a form in which the power storage device 231 is configured to be capable of individually charging and discharging each cell, the server 200 discharges only the target cell. However, the target cell may be discharged together with other cells. The second target value may be the same value as the upper limit SOC cancelled in S22 (current upper limit SOC). The second battery pack is a battery pack to which the current target cell does not belong. When the number of correction targets is two or more, the next target pack may be the second battery pack.

Subsequently, in S26, the server 200 updates the number (m) of uncorrected cells. Specifically, since the correction related to the target cell is completed by the processing of S23 to S25, a value obtained by subtracting 1 from the current m is set as a new m. Subsequently, in S27, the server 200 determines whether m becomes 0. When m is 1 or more (NO in S27), the target cell is changed, and the process returns to S23. Then, the processes of S23 to S25 are executed for the changed target cell. On the other hand, when m becomes 0 (YES in S27), the process proceeds to S28. In this embodiment, when the number of swollen cells is two or more, one correction is performed for each cell. Without being limited as such, correction may be performed on a plurality of cells at the same time.

In S28, the server 200 sets again the upper limit SOC (V2) cancelled in S22 for the target pack. Thus, the upper limit SOC of the target pack in the charging control (S103 in FIG. 2) is enabled.

In subsequent S29, the server 200 determines whether or not the above-described correction has been completed for all the correction targets. When the above-described correction is not completed for any correction target (NO in S29), the target pack is changed, and the process returns to S21. Then, the processing of S21 and subsequent steps is executed for the changed target pack. When the above-described correction is completed for all the correction targets (YES in S29), the process flow F3 (S20 in FIG. 3) ends. Thus, the process flow F2 illustrated in FIG. 3 ends. Thereafter, the process flow F2 is started again.

As described above, the charging method according to this embodiment includes the processes according to the process flows F1 to F3 (FIGS. 2 to 4). Each process is executed by one or more processors executing programs stored in one or more memories. However, these processes may be executed not by software but by hardware (electronic circuit).

The charging system according to the above embodiment includes battery packs 23-1 to 23-N and a server 200. Each of the battery packs 23-1 to 23-N includes a plurality of batteries (cells). The server 200 executes charging control for each of the battery packs 23-1 to 23-N in cooperation with the battery ECU 232 of each of the battery packs 23-1 to 23-N. Specifically, the server 200 executes the charging control of the battery pack so that the SOC of each battery included in the corresponding battery pack does not exceed the upper limit SOC set for the battery pack (S103 in FIG. 2). When none of the batteries included in the first battery pack is swollen, the server 200 sets V1 (first SOC value) as the upper limit SOC of the first battery pack (S132 in FIG. 3). When at least one battery included in the first battery pack swells, the server 200 sets V2 (a second SOC value lower than the first SOC value) as the upper limit SOC of the first battery pack (S131 in FIG. 3). When the battery swells, the upper limit SOC decreases from V1 to V2. As a result, the progress of swelling of the battery is suppressed.

In addition, when it is determined that at least one battery included in the first battery pack has been swollen and the SOC estimation error is large, the server 200 causes the SOC of the swollen battery to be higher than the second SOC value, and obtains a correction parameter for correcting the SOC estimation error related to the swollen battery (S13, S14, and S15 in FIG. 3, and S23 and S24 in FIG. 4). As a result, the SOC estimation error can be easily obtained accurately, and therefore, an appropriate correction parameter can be easily obtained. Even if the OCV-SOC curve of the cell changes due to swelling, the SOC of the cell can be easily estimated with high accuracy. Further, since the accuracy of SOC estimation is improved, swelling of the battery is easily suppressed by the upper limit SOC.

After the correction parameter is obtained, the server 200 discharges the swollen battery so that the SOC of the swollen battery becomes equal to or less than V2 (second SOC value), and charges the second battery pack with the discharged power (S25 of FIG. 4). As described above, the electric power discharged from the first battery pack for the SOC adjustment of the first battery pack is used to charge the other battery pack (second battery pack), so that the energy efficiency is improved.

In the charging system according to the above-described embodiment, when it is determined that the battery has been swollen and the SOC estimation error is large, after the server 200 executes the process of canceling the upper limit SOC for the battery (S22 of FIG. 4), the battery is charged so that the SOC of the battery becomes higher than V2 (second SOC value) (S23 of FIG. 4). Then, the server 200 obtains the second correction parameter in a state where the SOC of the battery is higher than V2 (S24 in FIG. 4). Thereafter, the server 200 discharges the battery until the SOC of the battery becomes equal to or less than V2 (S25 in FIG. 4), and sets V2 as the upper limit SOC for the battery (S28 in FIG. 4). In this way, by temporarily causing the SOC of the battery to be higher than the second SOC value, it is easy to obtain an appropriate second correction parameter. Then, by setting again the second SOC value as the upper limit SOC, the charging control of the battery is executed so that the SOC of the battery does not exceed the second SOC value, and the swelling of the battery is suppressed.

In S22 of FIG. 4, instead of the process of canceling the upper limit SOC for the battery, a process of setting the upper limit SOC to be higher than V2 (second SOC value) may be executed. For example, the server 200 may set the first SOC value as the upper limit SOC in S22 of FIG. 4. Then, the server 200 may return the upper limit SOC to the second SOC value in S28 of FIG. 4.

In the above embodiment, when it is determined that the battery swells and the SOC estimation error is large, the server 200 sets the SOC of the battery to V1 (third SOC value) higher than V2 (second SOC value) in S23 of FIG. 4. In the above embodiment, the first SOC value and the third SOC value are both V1. When the first SOC value is included in the steep region, the SOC estimation accuracy by the first estimation method is increased in the battery in the initial state. In addition, since the third SOC value is included in the steep region, it is possible to obtain the correction parameter related to the SOC estimation with high accuracy. Further, when the battery swells, the second SOC value lower than each of the first SOC value and the third SOC value is set as the upper limit SOC, whereby progress of swelling is easily suppressed. The third SOC value may be higher than V2 and lower than V1.

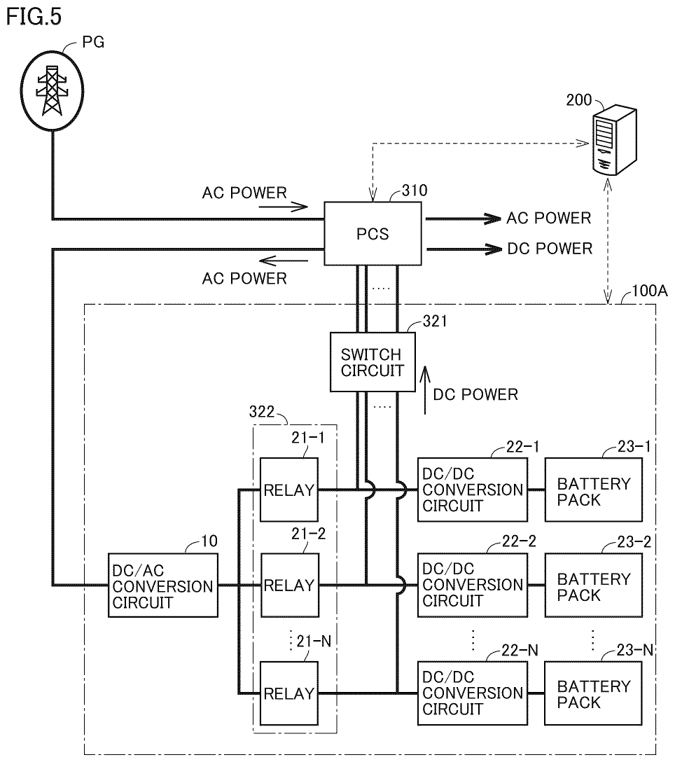

The power storage system may include a charging circuit and a discharging circuit separately. FIG. 5 is a diagram showing a modification of the power storage system shown in FIG. 1. In the power storage system 100A illustrated in FIG. 5, a PCS 310 and a switch circuit 321 are provided instead of the PCS 300 (FIG. 1). The PCS 310 incorporates a charging circuit and a discharging circuit. The charging circuit is connected to the power grid PG and the DC/AC conversion circuit 10, and outputs power supplied from the power grid PG to the DC/AC conversion circuit 10. The discharging circuit is connected to each of the DC/DC conversion circuits 22-1 to 22-N via the switch circuit 321. The switch circuit 321 connects the battery pack not to be charged among the battery packs 23-1 to 23-N to the discharging circuit and disconnects the battery pack to be charged from the discharging circuit. The discharging circuit is configured to supply power to the one or more power loads. Specifically, the discharging circuit outputs AC power supplied from the power grid PG and DC power supplied from one or more battery packs connected thereto. The DC power output from the discharging circuit may be converted into AC power by an inverter. On the other hand, the switch circuit 322 constituted by the relays 21-1 to 21-N connects the battery pack to be charged among the battery packs 23-1 to 23-N to the DC/AC conversion circuit 10, and disconnects the battery pack not to be charged from the DC/AC conversion circuit 10. The DC/AC conversion circuit 10 charges one or more connected battery packs with power from the power grid PG. Similarly to the switch circuit 322, the switch circuit 321 may include N relays.

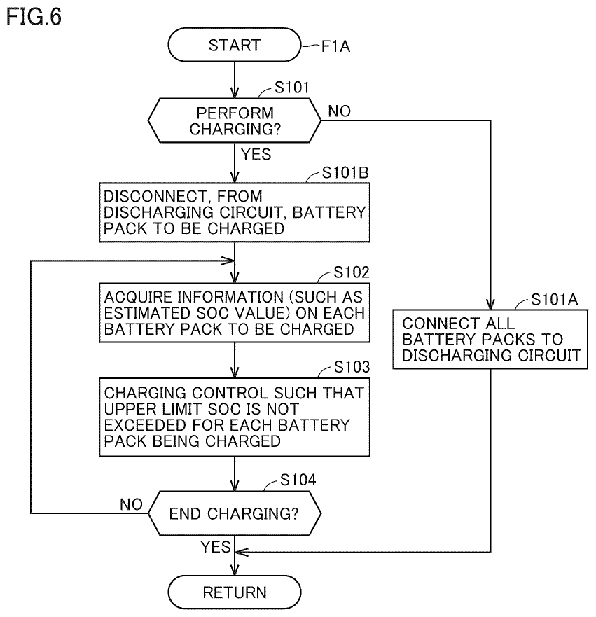

The server 200 illustrated in FIG. 5 may execute the process flow F1A illustrated in FIG. 6 instead of the process flow F1 (FIG. 2). FIG. 6 is a flowchart showing a modification of the process flow shown in FIG. 2. In the process flow F1A, when none of the battery packs is the battery pack to be charged (NO in S101), the server 200 connects all of the battery packs 23-1 to 23-N to the discharging circuit by the switch circuit 321 in S101A. When one or more battery packs are the battery pack to be charged (YES in S101), the server 200 disconnects the battery pack to be charged from the discharging circuit by the switch circuit 321 in S101B. According to the above system, during charging of a certain battery pack, discharge power from another battery pack is easily supplied to the power load.

In the above embodiment, the server 200 and the battery ECU 232 cooperate to function as a “controller” according to the present disclosure. Without being limited as such, a function (for example, an SOC estimation function) of the battery ECU 232 of each battery pack may be implemented in the server 200.

In the above-described embodiment and the modified example, the battery is charged by the power from the power grid PG. However, in a form in which the charging system includes a power generation device (for example, a solar panel provided in a building), the battery may be charged with electric power generated by the power generation device.

In the above embodiment, the charging system includes a plurality of battery packs. Without being limited as such, the number of battery packs may be one. One secondary battery may be employed instead of the battery assembly including a plurality of secondary batteries. In the above embodiment, the battery in the charging system is an LFP battery. However, the type of the battery in the charging system is arbitrary.

Although the present disclosure has been described and illustrated in detail, it is clearly understood that the same is by way of illustration and example only and is not to be taken by way of limitation, the scope of the present disclosure being interpreted by the terms of the appended claims.

What is claimed is:

1. A charging system comprising a controller configured to perform charging control of a battery in such a manner that an estimated SOC value of the battery does not exceed an upper limit SOC, wherein
the controller is configured to
set the upper limit SOC to a first SOC value, for the battery not having been swollen, and
set the upper limit SOC to a second SOC value lower than the first SOC value, for the battery having been swollen, and
in response to a determination that the battery has been swollen and an SOC estimation error is large, the controller is configured to cause an SOC of the battery to be higher than the second SOC value, and determine a correction parameter for correcting the SOC estimation error.

2. The charging system according to claim 1, wherein
in response to the determination that the battery has been swollen and the SOC estimation error is large, the controller is configured to
perform one of
cancelling the upper limit SOC for the battery, and
setting the upper limit SOC higher than the second SOC value, thereafter
charge the battery so that the SOC of the battery becomes higher than the second SOC value, and
determine the correction parameter in a state where the SOC of the battery is higher than the second SOC value, thereafter discharge the battery until the SOC of the battery becomes equal to or less than the second SOC value, and set the second SOC value as the upper limit SOC for the battery.

3. The charging system according to claim 1, wherein
in response to the determination that the battery has been swollen and the SOC estimation error is large, the controller is configured to cause the SOC of the battery to be a third SOC value higher than the second SOC value,
each of the first SOC value and the third SOC value is included in a steep region where dV/dQ of the battery is larger than a reference value,
the second SOC value is included in a flat region where dV/dQ of the battery is smaller than the reference value, and
dV/dQ of the battery is a ratio of an amount of change in voltage of the battery, to an amount of change in amount of power stored in the battery.

4. The charging system according to claim 3, further comprising:
a current sensor configured to detect a current flowing through the battery; and
a voltage sensor configured to detect a voltage of the battery, wherein
the controller is configured to determine whether or not the battery has been swollen, by using an integral value of charging current of the battery,
for the battery not having been swollen, the controller is configured to estimate the SOC of the battery by using the voltage of the battery detected by the voltage sensor,
for the battery having been swollen, the controller is configured to estimate the SOC of the battery by using the current of the battery detected by the current sensor, and the correction parameter, and
the controller is configured to determine whether or not the SOC estimation error is large, by using a value detected by the current sensor for the battery in which no current flows.

5. A charging system comprising a controller,
the charging system comprising: a first battery pack including a plurality of batteries; and a second battery pack including a plurality of batteries, wherein
the controller is configured to set an upper limit SOC for each of the first battery pack and the second battery pack,
for each of the first battery pack and the second battery pack, the controller is configured to perform charging control of the battery pack in such a manner that an estimated SOC value of each of the batteries included in the battery pack does not exceed the upper limit SOC that is set for the battery pack,
for the first battery pack in which none of the batteries included in the first battery pack has been swollen, the controller is configured to set a first SOC value as the upper limit SOC,
for the first battery pack in which at least one battery included in the first battery pack has been swollen, the controller is configured to set, as the upper limit SOC, a second SOC value lower than the first SOC value,
in response to a determination that at least one battery included in the first battery pack has been swollen and an SOC estimation error is large, the controller is configured to cause an SOC of the swollen battery to be higher than the second SOC value, and determine a correction parameter for correcting the SOC estimation error for the swollen battery, and
after the correction parameter is acquired, the controller is configured to discharge the swollen battery so that the SOC of the swollen battery becomes equal to or less than the second SOC value, and charge the second battery pack with power discharged from the swollen battery.
